(19) United States
(12) Patent Application Publication
(10) Pub. No.: US 2005/0040895 A1
(43) Pub. Date: Feb. 24, 2005

(54) [LOW POWER CONSUMPTION CIRCUIT AND DELAY CIRCUIT THEREOF]

(76) Inventors: Hong-Gee Fang, Hsinchu (TW); Wen-Chieh Lee, Hsinchu (TW); Chih-Yuan Cheng, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,764

(22) Filed: Aug. 2, 2004

(30) Foreign Application Priority Data
Aug. 19, 2003 (TW) 92122707

(51) Int. Cl. H03L 7/00

(52) U.S. Cl. 331/17

(57) ABSTRACT

A low power consumption oscillation circuit and a delay circuit thereof are disclosed. The circuit comprises an enable circuit, an oscillator delay circuit and a feedback control network. The enable circuit is adapted for receiving an enable signal and performing an initial oscillation. The enable circuit outputs an initial oscillation signal according to a feedback control signal. The oscillator delay circuit is coupled to the enable circuit and is adapted for alternately generating a high and a low level oscillation signals according to the initial oscillation signal. The feedback control network is coupled to the oscillator delay circuit and is adapted for integrating the high and the low level oscillation signals to generate a feedback control signal and outputting the feedback control signal to the enable the circuit for activating next oscillation.

### CROSS REFERENCE TO RELATED APPLICATIONS

This application claims the priority benefit of Taiwan application serial no. 92122707, filed Aug. 19, 2003.

### BACKGROUND OF INVENTION

1. Field of the Invention

The present invention relates to an oscillation circuit, and more particularly to a low power consumption oscillation circuit and a delay circuit thereof.

2. Description of the Related Art

Traditionally, a ring oscillator can obtain a great oscillation period by coupling a plurality of gate delays in series. Oscillation period may also be achieved by applying a loading device with long charging and discharging time. For example, a plurality of gate delays is coupled in series. A passive loading device is coupled between two inverters for achieving such delay. These two methods, however, consume considerable amount of power.

FIG. 1 is a block diagram showing a prior art ring oscillator. The prior art ring oscillator is disclosed in U.S. Pat. No. 6,188,293. The prior art ring oscillator comprises a constant voltage generating circuit 102, an inverter circuit 104 and a constant current element 106. In the ring oscillator, the inverter circuit comprises alternatively coupling inverters and loading devices. The prior art technology applies the constant voltage generating circuit 102 to control voltage and the constant current element 106 to restrict current for achieving low power consumption.

### SUMMARY OF INVENTION

Accordingly, the present invention is directed to a low power consumption oscillation circuit and a delay circuit thereof to reduce the power consumption.

According to an embodiment of the present invention, the low power consumption oscillation circuit comprises an enable circuit, an oscillator delay circuit and a feedback control network. The enable circuit activates an initial operation according to an enable signal received from the external circuits. The enable circuit outputs an initial oscillation signal according a feedback control signal. The oscillator delay circuit is coupled to the enable circuit for receiving the initial oscillation signal from the enable circuit and alternatively generating a high level oscillation signal oscillating in a high voltage area and a low level oscillation signal oscillating in a low voltage area according the initial oscillation signal. The high voltage area is between the high working voltage and a low-limit voltage higher than the low working voltage, and the low voltage area is between the low working voltage and an up-limit voltage lower than the high working voltage. The feedback control network is coupled to the oscillator delay circuit, integrating the high level oscillation signal and the low level oscillation signal as the feedback control signal, outputting the feedback control signal to the enable circuit for activating a next oscillation. Therefore, the oscillation circuit becomes a ring oscillator.

The delay circuit of the low power consumption oscillation circuit, according to an embodiment of the present invention, operates according to a high working voltage and a low working voltage. The delay circuit comprises a pull-up device, a pull-down device, a loading device, a first output terminal and a second output terminal. The pull-up device is coupled to the high working voltage and is adapted for receiving a first signal. The pull-down device is coupled to the low working voltage and is adapted for receiving a second signal. The loading device is coupled to the pull-up and the pull-down devices and disposed between the pull-up and the pull-down devices. The first output terminal is coupled to the pull-up device and the loading device and disposed between the pull-up device and the loading device and is adapted for outputting a signal oscillating in a high voltage area. The second output terminal is coupled to the pull-down device and the loading device and disposed between the pull-down device and the loading device and is adapted for outputting a signal oscillating in a low voltage area. The pull-up device comprises a P-type semiconductor device. The pull-down device comprises an N-type semiconductor device. The pull-up and the pull-down devices of the delay circuit may receive an oscillation signal.

The oscillation signal is processed into the high level oscillation signal oscillating in the high voltage area and the low level oscillation signal oscillating in the low voltage area, therefore the power consumption is reduced. The feedback control network resets the oscillator delay circuit and reactivates oscillation. Without being reset by the feedback control network, the phase shift of the input of the oscillator delay circuit becomes worse by the multiple-level series method. The cut-off working areas of the pull-up and the pull-down overlap, oscillation of the oscillation signal fails and the oscillation signal cannot be transmitted.

In order to make the aforementioned and other objects, features and advantages of the present invention understandable, a preferred embodiment accompanied with figures is described in detail below.

### BRIEF DESCRIPTION OF DRAWINGS

FIG. 1 is a block diagram showing a prior art ring oscillator.

FIG. 2 is a schematic block diagram showing a low power consumption oscillation circuit according to an embodiment of the present invention.

FIG. 3 is a schematic block diagram showing an enable circuit of the low power consumption oscillation circuit shown in FIG. 2.

FIG. 4 is a schematic block diagram showing an oscillator delay circuit of the low power consumption oscillation circuit shown in FIG. 2.

FIG. 5 is a schematic block diagram showing a feedback control network of the low power consumption oscillation circuit shown in FIG. 2.

FIGS. 6A-6D are waveform simulations at points 523, 221, 224 and 526 of the feedback control network shown in FIG. 5.

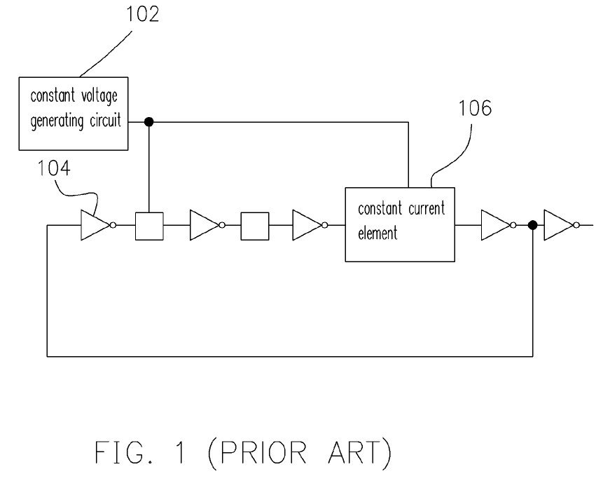

### DETAILED DESCRIPTION

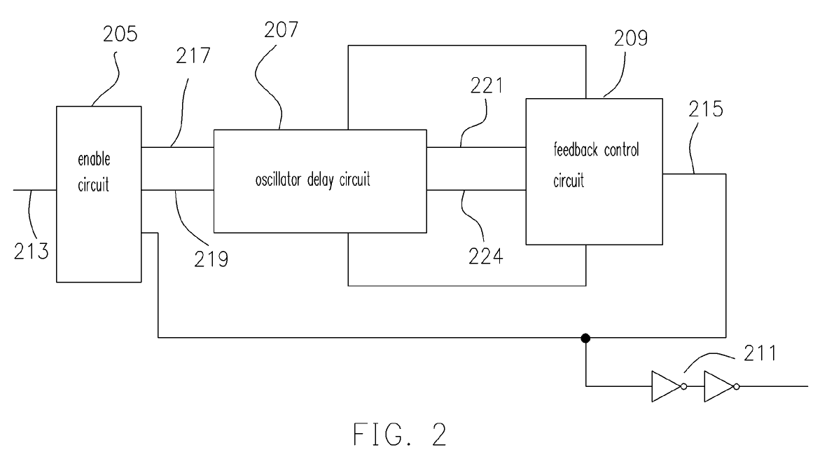

FIG. 2 is a schematic block diagram showing a low power consumption oscillation circuit according to an embodiment of the present invention. The low power consumption oscillation circuit comprises an enable circuit 205, an oscillator delay circuit 207 and a feedback control network 209. The enable circuit 205 performs an initial oscillation according to an enable signal 213 received from an external circuit. The enable circuit 205 then outputs an initial oscillation signal according to a feedback control signal 215. The oscillator delay circuit 207 receives the initial oscillation signal from the output terminals 217 and 219 of the enable circuit 205. The oscillator delay circuit 207 alternately generates a high level oscillation signal 221 oscillating in a high voltage area and a low level oscillation signal 224 oscillating in a low voltage area according to the initial oscillation signal. The high voltage area is between the high working voltage and a low-limit voltage higher than the low working voltage, and the low voltage area is between the low working voltage and an up-limit voltage lower than the high working voltage. The feedback control network 209 is coupled to the oscillator delay circuit 207 and is adapted for integrating the high level oscillation signal 221 and the low level oscillation signal 224 to generate a feedback control signal 215 and outputting the feedback control signal 215 to the enable circuit 205. The feedback control signal 215 is reverse to the initial oscillation signal. The oscillation circuit performs next oscillation in response to the feedback of the feedback control signal 215 to the enable circuit 205.

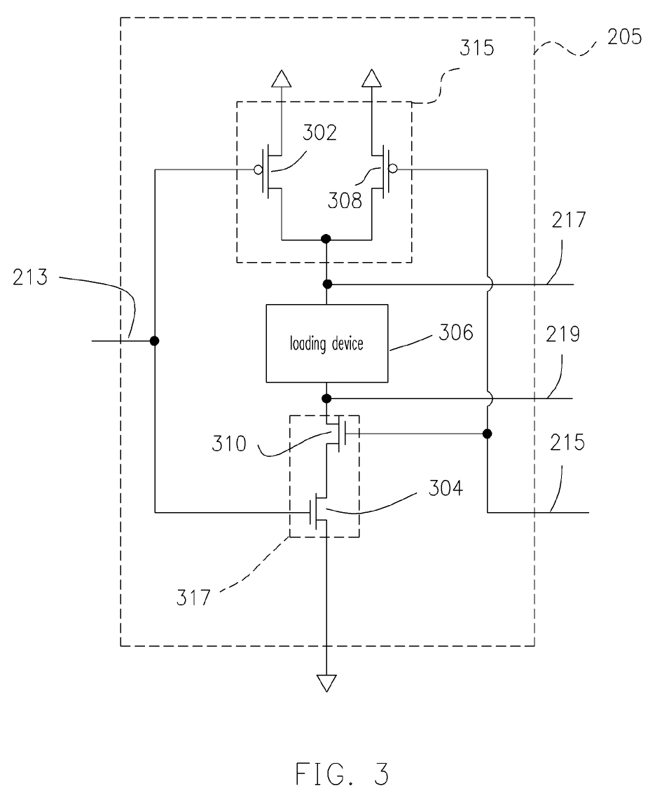

FIG. 3 is a schematic block diagram showing an enable circuit according to FIG. 2 of the present invention. The enable circuit 205 comprises a P-type semiconductor combination 315, an N-type semiconductor combination 317 and a loading device 306. The P-type semiconductor combination 315 comprises P-type semiconductor devices 302 and 308 coupled in series. The N-type semiconductor combination 315 comprises N-type semiconductor devices 304 and 310 coupled in series. The loading device is coupled to the P-type semiconductor device 308 and the N-type semiconductor device 310 and disposed between the P-type semiconductor device 308 and the N-type semiconductor device 310. The enable circuit 205 performs an initial oscillation after receiving an enable signal 213 from an external circuit. The feedback control signal 215 then activates the next oscillation. One of ordinary skill in the art will understand that this embodiment applies a NAND gate. But the present invention is not limited thereto. For example, a NOR gate comprising two P-type semiconductor devices coupled in series of the P-type semiconductor combination and two N-type semiconductor devices coupled in parallel of the N-type semiconductor combination can be applied. In this embodiment, the P-type semiconductor combination 315 outputs a high level oscillation signal 217 according to either the enable signal 213 or the feedback control signal 215. The N-type semiconductor combination 317 outputs a low level oscillation signal 219 according to either the enable signal 213 or the feedback control signal 215. When the loading device 306 has low resistance, the voltage areas in which the high-level oscillation signal 217 and the low level oscillation signal 219 oscillate overlap. The enable circuit 205 mainly serves for receiving the feedback control signal 215 and maintaining the next oscillation of the oscillation circuit, after the first oscillation, which is activated by the enable signal 213.

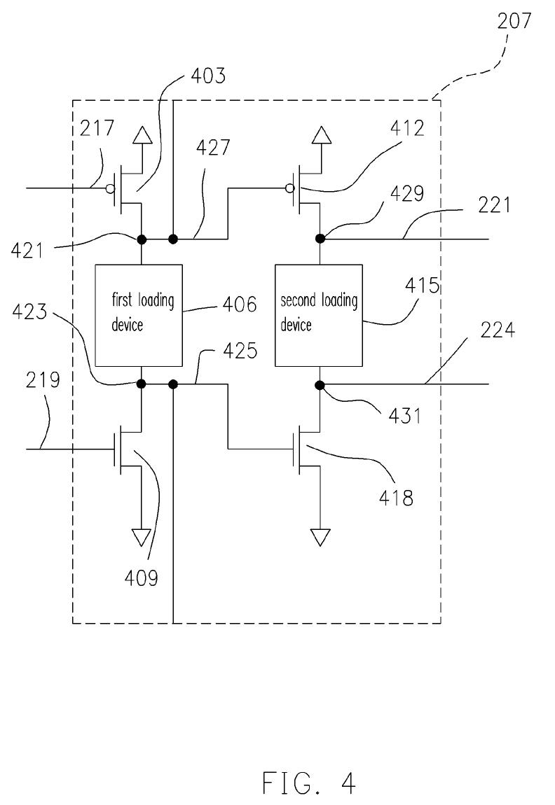

FIG. 4 is a schematic block diagram showing an oscillator delay circuit of the low power consumption oscillation circuit shown in FIG. 2. The oscillator delay circuit 207 comprises at least one delay. It may comprise a plurality of delay circuits coupled in series. In this embodiment, the first delay comprises a first pull-up device 403, a first pull-down device 409 and a first loading device 406. The first loading device 406 is coupled to the first pull-up device 403 and the first pull-down device 409 and disposed between the first pull-up device 403 and the first pull-down device 409. The second delay comprises a second pull-up device 412, a second pull-down device 418 and a second loading device 415. The second loading device 415 is coupled to the second pull-up device 412 and the second pull-down device 418 and disposed between the second pull-up device 412 and the second pull-down device 418. The first delay circuit further comprises a first output terminal 421 and a second output terminal 423. The second delay circuit further comprises a first output terminal 429 and a second output terminal 431. When the voltage of the low level oscillation signal 219 increases, the pull-up device 403 of the first delay circuit is turned off and the pull-down device 409 is turned on immediately. The input signal of the pull-down device 418 of the second delay circuit, i.e. the voltage of the low level oscillation signal 425, decreases so that the pull-down device 418 is turned off. The low level oscillation signal 425 inputted to the pull-down device 418 gradually pulls down the input signal of the pull-up device 412, i.e. the voltage of the high level oscillation signal 427, via the first loading device. When the voltage of the high level oscillation signal 427 reaches a specific voltage, the pull-up device 412 of the second delay circuit is turned on, outputting the high level oscillation signal 221 to a following functional circuit.

Accordingly, the pull-up and the pull-down devices alternately transmit the high and low level oscillation signals. The loading device with high resistance and high capacitance restricts current flowing therethrough and generates a phase difference for the high and low level oscillation signals. The pull-up and the pull-down devices will not turn on simultaneously. As a result, a temporary short current between the high and low working voltages can be avoided. The loading device with the high resistance and capacitance contributes persistent oscillation. A loading device with high capacitance and low resistance, however, may not contribute to low power consumption. As a result, the loading device with a high resistance is more desired. Not every high and low level oscillation signals of each delay circuit of the oscillation circuit are inputted from the enable circuit 205. For example, the high level oscillation signal 427 and the low level oscillation signal 425 of the second delay circuit are inputted from the first delay circuit. The input and output signals of every delay circuit are reverse to each other. The oscillator delay circuit 207 generates the high and low level oscillation signals with different phases via the loading device for controlling charging or discharging of the pull-up and pull-down devices. In addition to determining the oscillation periods and the power consumed by the circuit, the loading device restricts the current flowing through the feedback control network 209 by providing signals with different voltages.

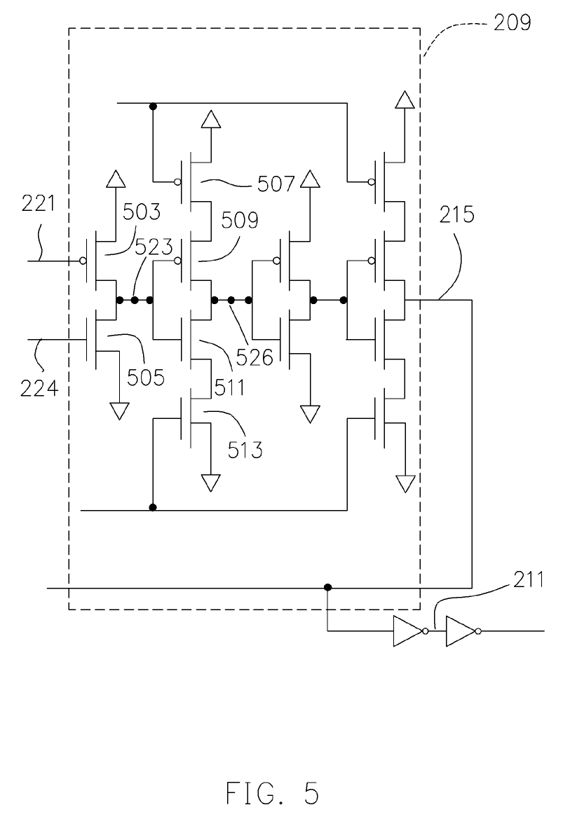

FIG. 5 is a schematic block diagram showing a feedback control network of the low power consumption oscillation circuit shown in FIG. 2. In this embodiment, the feedback control network 209 comprises only one inverter or a plurality of inverters. Every inverter comprises a P-type semiconductor device and an N-type semiconductor device coupled in series, such as the P-type semiconductor device 503 and the N-type semiconductor device 505 shown in FIG. 5. After receiving the high level oscillation signal 221 and the low level oscillation signal 224 outputted from the oscillator delay circuit 207, the feedback control network modifies the signals and outputs a feedback control signal 215 to the enable circuit 205 for resetting the oscillation signals.

In another embodiment of the present invention, each of the every other inverters further comprises an external P-type semiconductor device 507 coupled to the P-type semiconductor device 509 in series and an external N-type semiconductor device 513 coupled to the N-type semiconductor device 511 in series as another external control inverter. Accordingly the external control inverter comprises the inverter comprising the P-type semiconductor device 509 and the N-type semiconductor device 511, and the inverter comprising the external P-type semiconductor device 507 and the external N-type semiconductor device 513. The external P-type semiconductor device 507 is coupled to the high working voltage and the P-type semiconductor device 509 and disposed between the high working voltage and the P-type semiconductor device 509; the external N-type semiconductor device 513 is coupled to the low working voltage and the N-type semiconductor device 511 and disposed between the low working voltage and the N-type semiconductor device 511.

The external P-type semiconductor device 507 and the external N-type semiconductor device 513 separately receives the high and low level oscillation signals with same phase outputted from the even delay circuit counted backward from the oscillator delay circuit 207. In this embodiment, the external P-type semiconductor device 507 and the external N-type semiconductor device 513 receive the high level oscillation signal 427 and the low level oscillation signal 425 outputted from the first delay circuit of the oscillation circuit. The feedback control network 209 modifies the waveforms and the time sequences of the signals 221 and 224 outputted from the oscillator delay circuit 207. After such modification, the signals are outputted to the enable circuit 205 for activating the next oscillation. The input signal from the oscillator delay circuit received by the inverter and the input signal of the inverter should be compensated for each other, or the cut-off areas of the transistors overlap. Due to the overlap, the transmission route for the oscillation signal may be terminated and oscillation cannot be continued. In addition, the feedback control network 209 is further coupled to a buffer device 211. The buffer device 211 comprises one inverter or a plurality of inverters coupled in series for persistent oscillation of the circuit.

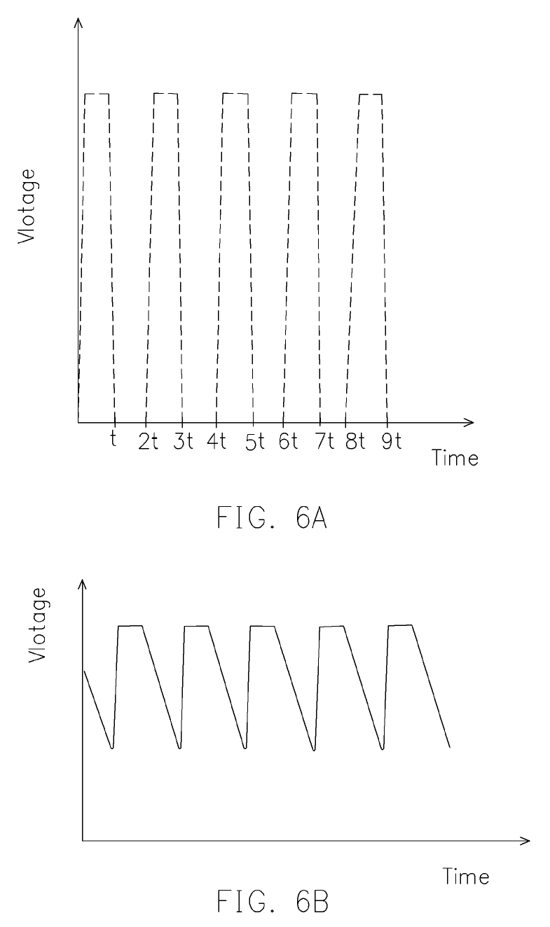

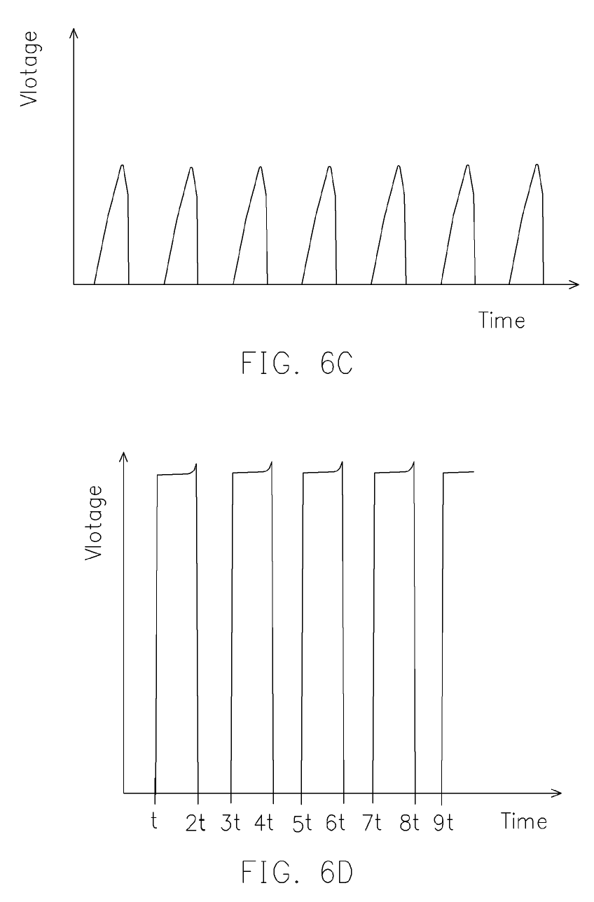

FIGS. 6A-6D are waveform simulations at points 523, 221, 224 and 526 of the feedback control network shown in FIG. 5. In the time axis, t represents a half period. Referring to FIG. 6A, a signal with a full amplitude at point 523 between an inverter and a next level inverter is shown. Referring to FIG. 6B, the high level oscillation signal 221 before the signal outputted from the delay circuit to the feedback control network 209 is shown. The amplitude of the signal is a half of the full amplitude. Referring to FIG. 6C, the low level oscillation signal 224 before the signal outputted from the delay circuit to the feedback control network 209 is shown. The amplitude of the signal is a half of the full amplitude. Referring to FIGS. 6B and 6C, no overlap of the working areas occurs after the device receives the high and low level oscillation signals. Referring to FIG. 6D, the feedback control signal 526 outputted from the external control inverter, which is reverse to the signals at the point 523, is shown.

Due to the high resistance of the loading devices between the pull-up and pull-down devices, the pull-up and pull-down devices of the oscillator delay circuit 207 do not turn on simultaneously. The issue of temporary short current can be reduced. Even when operating under normal working voltage, the oscillator delay circuit 207 consumes low power. The loading device with high resistance can comprise, for example, an active device. The high level oscillation signal and the low level oscillation signal alternately generated from the oscillation signal separately oscillate in the high voltage area and the low voltage area. Full-amplitude charging and discharging are not required to achieve low power consumption. Electrical energy is proportional to the square of voltage. It means that when the voltage is reduced to one half, the electrical energy is reduced to one fourth. One of ordinary skill in the art will understand that the oscillation circuit is equivalent to a ring oscillator. The present invention, however, is not limited thereto.

Although the present invention has been described in terms of exemplary embodiments, it is not limited thereto. Rather, the appended claims should be constructed broadly to include other variants and embodiments of the invention which may be made by those skilled in the field of this art without departing from the scope and range of equivalents of the invention.

1. A low power consumption oscillation circuit, the oscillation circuit activating an initial oscillation operation according to an enable signal, and operating according to a high working voltage and a low working voltage, comprising:
an enable circuit, outputting an initial oscillation signal after the initial oscillation operation according a feedback control signal;
an oscillator delay circuit, coupled to the enable circuit, receiving the initial oscillation signal from the enable circuit and alternately generating a high level oscillation signal oscillating in a high voltage area and a low level oscillation signal oscillating in a low voltage area according the initial oscillation signal, wherein the high voltage area is between the high working voltage and a low-limit voltage higher than the low working voltage, and the low voltage area is between the low working voltage and an up-limit voltage lower than the high working voltage; and
a feedback control network, coupled to the oscillator delay circuit, integrating the high level oscillation signal and the low level oscillation signal as the feedback control signal and outputting the feedback control signal to the enable circuit.

2. The low power consumption oscillation circuit of claim 1, wherein the initial oscillation signal outputted from the enable circuit comprises two partial signals separately oscillating in the high voltage area and low voltage area.

3. The low power consumption oscillation circuit of claim 2, wherein the enable circuit comprises:
a P-type semiconductor device combination, coupled to the high working voltage, outputting the high level oscillation signal according to the feedback control signal;
an N-type semiconductor device combination, coupled to the low working voltage, outputting the high level oscillation signal according to the feedback control signal; and
a loading device, coupled to the P-type semiconductor device combination and N-type semiconductor device combination and disposed between the P-type semiconductor device combination and N-type semiconductor device combination.

4. The low power consumption oscillation circuit of claim 2, wherein the oscillator delay circuit comprises a delay circuit.

5. The low power consumption oscillation circuit of claim 4, wherein the delay circuit comprises:
a pull-up device coupled to the high working voltage, receiving the high level oscillation signal outputted from the enable circuit;
a pull-down device coupled to the low working voltage, receiving the low level oscillation signal outputted from the enable circuit;
a loading device, coupled to the pull-up and pull-down devices and disposed between the pull-up and pull-down devices;
a first output terminal, coupled to the pull-up device and the loading device and disposed between the pull-up device and the loading device, outputting the high level oscillation signal to the feedback control network; and
a second output terminal, coupled to the pull-down device and the loading device and disposed between the pull-down device and the loading device, outputting the low level oscillation signal to the feedback control network.

6. The low power consumption oscillation circuit of claim 2, wherein the oscillation delay circuit comprises a plurality of delay circuits.

7. The low power consumption oscillation circuit of claim 6, wherein the delay circuits comprise:
a first delay circuit, coupled to the enable circuit; and
a plurality of backend delay circuits, the backend delay circuits comprising delay circuits connected in series, wherein a second delay circuit is coupled to the first delay circuit, and an output delay circuit is coupled to the feedback control network.

8. The low power consumption oscillation circuit of claim 7, wherein the first delay circuit comprises:
a pull-up device, coupled to the high working voltage, receiving the high level oscillation signal outputted from the enable circuit;
a pull-down device, coupled to the low working voltage, receiving the low level oscillation signal outputted from the enable circuit;
a loading device, coupled to the pull-up and pull-down devices and disposed between the pull-up and pull-down devices;
a first output terminal, coupled to the pull-up device and the loading device and disposed between the pull-up device and the loading device, outputting the high level oscillation signal to the feedback control network; and
a second output terminal, coupled to the pull-down device and the loading device and disposed between the pull-down device and the loading device, outputting the low level oscillation signal to the feedback control network.

9. The low power consumption oscillation circuit of claim 7, wherein the delay circuits comprise:
a pull-up device, coupled to the high working voltage, receiving the high level oscillation signal outputted from a front end of the pull-up device;
a pull-down device, coupled to the low working voltage, receiving the low level oscillation signal outputted from a front end of the pull-down device;
a loading device, coupled to the pull-up and pull-down devices and disposed between the pull-up and pull-down devices;
a first output terminal, coupled to the pull-up device and the loading device and disposed between the pull-up device and the loading device, outputting the high level oscillation signal to a backend of the pull-up device; and
a second output terminal, coupled to the pull-down device and the loading device and disposed between the pull-down device and the loading device, outputting the low level oscillation signal to the pull-down device.

10. The low power consumption oscillation circuit of claim 6, wherein the feedback control network comprises a plurality of inverters, the inverters comprising:
a plurality of inverters, each of the inverters comprising a P-type semiconductor device and an N-type semiconductor device; and
a plurality of external control inverters, each of the external control inverters comprising a P-type semiconductor device, an N-type semiconductor device, an external P-type semiconductor device and an external N-type semiconductor device, wherein each of the inverters and each of the external control inverters are alternately coupled to each other in series.

11. The low power consumption oscillation circuit of claim 10, wherein the external control inverters comprise:
the external P-type semiconductor device, coupled to the high working voltage and the P-type semiconductor device and disposed between the high working voltage and the P-type semiconductor device, receiving the high level oscillation signal outputted from an even delay circuit counted backward; and
the external N-type semiconductor device, coupled to the low working voltage and the N-type semiconductor device and disposed between the low working voltage and the N-type semiconductor device, receiving the low level oscillation signal outputted from the even delay circuit counted backward.

12. The low power consumption oscillation circuit of claim 1, wherein the oscillator delay circuit comprises a delay circuit.

13. The low power consumption oscillation circuit of claim 12, wherein the delay circuit comprises:
a pull-up device, coupled to the high working voltage, receiving the initial oscillation signal;
a pull-down device, coupled to the low working voltage, receiving the initial oscillation signal;
a loading device, coupled to the pull-up and pull-down devices and disposed between the pull-up and pull-down devices;
a first output terminal, coupled to the pull-up device and the loading device and between the pull-up device and the loading device, outputting the high level oscillation signal; and
a second output terminal, coupled to the pull-down device and the loading device and disposed between the pull-down device and the loading device, outputting the low level oscillation signal.

14. The low power consumption oscillation circuit of claim 1, wherein the oscillation delay circuit comprises a plurality of delay circuits.

15. The low power consumption oscillation circuit of claim 14, wherein the delay circuits comprise:
a first delay circuit, coupled to the enable circuit; and
a plurality of backend delay circuits, the backend delay circuits comprising delay circuits connected in series, wherein a second delay circuit is coupled to the first delay circuit, and an output delay circuit is coupled to the feedback control network.

16. The low power consumption oscillation circuit of claim 15, wherein the first delay circuit comprises:
a pull-up device, coupled to the high working voltage, resceiving the initial oscillation signal;
a pull-down device, coupled to the low working voltage, receiving the initial oscillation signal;
a loading device, coupled to the pull-up and pull-down devices and disposed between the pull-up and pull-down devices;
a first output terminal, coupled to the pull-up device and the loading device and disposed between the pull-up device and the loading device, outputting the high level oscillation signal to the second delay circuit; and
a second output terminal, coupled to the pull-down device and the loading device and disposed between the pull-down device and the loading device, outputting the low level oscillation signal to the second delay circuit.

17. The low power consumption oscillation circuit of claim 15, wherein the delay circuits comprise:
a pull-up device, coupled to the high working voltage, receiving the high level oscillation signal outputted from a front end of the pull-up device;
a pull-down device, coupled to the low working voltage, receiving the low level oscillation signal outputted from a front end of the pull-down device;
a loading device, coupled to the pull-up and pull-down devices and disposed between the pull-up and pull-down devices;
a first output terminal, coupled to the pull-up device and the loading device and disposed between the pull-up device and the loading device, outputting the high level oscillation signal; and
a second output terminal, coupled to the pull-down device and the loading device and disposed between the pull-down device and the loading device, outputting the low level oscillation signal.

18. The low power consumption oscillation circuit of claim 14, wherein the feedback control network comprises a plurality of inverters and a plurality of external control inverters, and each of the inverters and each of the external control inverters are alternately coupled to each other in series.

19. The low power consumption oscillation circuit of claim 18, wherein the external control inverters comprise:
an inverter, comprising a P-type semiconductor device and an N-type semiconductor device coupled in series;
an external P-type semiconductor device, coupled to the high working voltage and the P-type semiconductor device and disposed between the high working voltage and the P-type semiconductor device, receiving the high level oscillation signal outputted from an even delay circuit counted backward; and
an external N-type semiconductor device, coupled to the low working voltage and the N-type semiconductor device and disposed between the low working voltage and the N-type semiconductor device, receiving the low level oscillation signal outputted from the even delay circuit counted backward.

20. A delay circuit of a low power consumption oscillation circuit, operating according to a high working voltage and a low working voltage, comprising:
a pull-up device, coupled to the high working voltage, receiving a first signal;
a pull-down device, coupled to the low working voltage, receiving a second signal;
a loading device, coupled to the pull-up and the pull-down devices and disposed between the pull-up and the pull-down devices;
a first output terminal, coupled to the pull-up device and the loading device and disposed between the pull-up device and the loading device, outputting a signal oscillating in a high voltage area; and
a second output terminal, coupled to the pull-down device and the loading device and disposed between the pull-down device and the loading device, outputting a signal oscillating in a low voltage area, wherein the high voltage area is between the high working voltage and a low-limit voltage higher than the low working voltage, and the low voltage area is between the low working voltage and an up-limit voltage lower than the high working voltage.

21. The delay circuit of a low power consumption oscillation circuit of claim 20, wherein the first signal is as same as the second signal.

22. The delay circuit of a low power consumption oscillation circuit of claim 20, wherein the pull-up device comprises a P-type semiconductor device.

23. The delay circuit of a low power consumption oscillation circuit of claim 20, wherein the pull-down device comprises an N-type semiconductor device.

24. The delay circuit of a low power consumption oscillation circuit of claim 20, wherein the loading device comprises an active device.

25. The delay circuit of a low power consumption oscillation circuit of claim 1, wherein the feedback control network comprises an inverter.

26. The delay circuit of a low power consumption oscillation circuit of claim 25, wherein the inverter comprises a P-type semiconductor device and an N-type semiconductor which are coupled in series.
